(19) United States
(12) Patent Application Publication
(10) Pub. No.: US 2011/0168226 A1
(43) Pub. Date: Jul. 14, 2011

(54) SOLAR CELL MODULE AND METHOD OF MANUFACTURING THE SAME

(75) Inventors: Yun-Gi KIM, Yongin-si (KR); Hwa-Young KO, Seoul (KR)

(73) Assignee: SAMSUNG ELECTRONICS CO., LTD., Suwon-si (KR)

(21) Appl. No.: 12/820,524

(22) Filed: Jun. 22, 2010

(30) Foreign Application Priority Data
Jan. 11, 2010 (KR) 10-2010-0002328

(51) Int. Cl. H01L 31/042; H01L 31/18

(52) U.S. Cl. 136/244; 438/72; 438/73; 257/E31.119; 257/E31.11

(57) ABSTRACT

A solar cell module includes a plurality of solar cells connected to each other, each solar cell of the plurality of solar cells independently includes a semiconductor substrate, one n+ region and one p+ region disposed on one side of the semiconductor substrate and separated from each other, at least one first electrode and at least one second electrode, in which the at least one first electrode is electrically connected to the n+ region and the at least one second electrode is electrically connected to the p+ region, and a first trench and a second trench disposed on each of the plurality of solar cells, wherein the first trench is disposed on the one side of the semiconductor substrate and the second trench is disposed on the other opposite facing side of the semiconductor substrate, the first and second trenches are separated from each other.

### CROSS-REFERENCE TO RELATED APPLICATION

This application claims priority to Korean Patent Application No. 10-2010-0002328, filed on Jan. 11, 2010, and all the benefits accruing therefrom under 35 U.S.C. §119, the content of which in its entirety is herein incorporated by reference.

### BACKGROUND

1) Field

This general inventive concept relates to a solar cell module and a method of manufacturing the same.

2) Description of the Related Art

A solar cell is a photoelectric conversion device that transforms solar energy into electrical energy, and has attracted much attention as a renewable and pollution-free next generation energy source.

A solar cell typically includes p-type and n-type semiconductors. The solar cell produces electrical energy by transferring electrons and holes to the n-type and p-type semiconductors, respectively, and then collecting electrons and holes in electrodes, when an electron-hole pair (“EHP”) is produced by solar light energy absorbed in a photoactive layer inside the semiconductors.

Solar cells are often connected in series as a solar cell module, resultantly creating an additive voltage. Up to the present, a solar cell module is typically manufactured by separating the solar cells and then rearranging and wiring the solar cells. However, the aforementioned manufacturing method requires a wide area of the solar cell module as well as an additional complex process, such as regulating a distance between each solar cell in the solar cell module and arranging the solar cells, for example.

### SUMMARY

One aspect of the present invention includes a solar cell module including a plurality of solar cells, wherein the solar cell module is manufactured without a process of separating each of the plurality of solar cells.

Another aspect of the present invention includes a method of manufacturing the solar cell module.

According to one aspect of the present invention, a solar cell module includes a plurality of solar cells connected to one another, each solar cell of the plurality of solar cells independently includes a semiconductor substrate, one n+ region and one p+ region disposed on one side of the semiconductor substrate and separated from each other, and at least one first electrode and at least one second electrode, in which the at least one first electrode is electrically connected to the n+ region and the at least one second electrode is electrically connected to the p+ region; and

a first trench and a second trench disposed on each of the plurality of solar cells, wherein the first trench is disposed on the one side of the semiconductor substrate and the second trench is disposed on the other opposite facing side of the semiconductor substrate, the first and the second trenches are separated from each other.

A plurality of the n+ and p+ regions included in the solar cell module may be alternately disposed on the one side of the semiconductor substrate.

The semiconductor substrate may have a thickness from about 50 micrometers (μm) to about 300 μm.

In the solar cell module, a sum of depths of the first and second trenches may be greater than a thickness of the semiconductor substrate.

A difference calculated by subtracting a thickness of the semiconductor substrate from a sum of depths of the first and second trenches may be greater than a length of a mean free path of electrons and holes produced from the semiconductor substrate.

The first trench may have a width from about 20 μm to about 50 μm, and the second trench may have a width from about 20 μm to about 50 μm.

In the solar cell module, each of the plurality of solar cells may further include an anti-reflection coating layer on the one side of the semiconductor substrate. In addition, each of the plurality of solar cells may further include a dielectric layer on the other opposite facing side of the semiconductor substrate.

The solar cell module may further include a first passivation layer on a surface of the first trench and a second passivation layer on a surface of the second trench.

According to another aspect of the present invention, a method of manufacturing a solar cell module includes fabrication of a plurality of solar cells connected to one another, each solar cell of the plurality of solar cells independently includes a semiconductor substrate, one n+ region and one p+ region one side of the semiconductor substrate and the second trench is disposed on the other opposite facing side of the semiconductor substrate, the first and the second trenches are separated from each other.

The solar cell module may be fabricated by alternately disposing a plurality of the n+ and p+ regions on the one side of the semiconductor substrate.

Furthermore, each of the plurality of solar cells may be fabricated by disposing an anti-reflection coating layer on the one side of the semiconductor substrate and disposing a dielectric layer on the other opposite facing side of the semiconductor substrate.

The first and second trenches may be disposed through a laser etching process, a sawing process, a trench etching process, or any combinations thereof, but are not limited thereto.

In addition, the first and second trenches may be disposed by removing parts damaged due to the laser etching process, the sawing process, the trench etching process, or any combinations thereof, but are not limited thereto.

The method may further include disposing a first passivation layer on a surface of the first trench, disposing a second passivation layer on a surface of the second trench, or a combination thereof.

Further, other aspects of the present invention will be described in the following detailed description.

### BRIEF DESCRIPTION OF THE DRAWINGS

The above and other aspects of the present invention will become more readily apparent by describing in further detail aspects thereof with reference to the accompanying drawings, in which:

FIG. 1 is a partial cross-sectional view of a solar cell module according to one aspect of the present invention; and

FIGS. 2A to 2O are partial cross-sectional views showing processes of manufacturing the solar cell module according to another aspect of the present invention.

### DETAILED DESCRIPTION

The general inventive concept now will be described more fully hereinafter with reference to the accompanying drawings, in which various exemplary embodiments are shown. This invention may, however, be embodied in many different forms, and should not be construed as limited to the embodiments set forth herein. Rather, these exemplary embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, exemplary embodiments of the present invention will be described in further detail with reference to the accompanying drawings.

According to one aspect of the present invention, a solar cell module includes a plurality of solar cells connected to one another, each solar cell of the plurality of solar cells independently includes a semiconductor substrate, one n+ region and one p+ region disposed on one side of the semiconductor substrate and separated from each other, and at least one first electrode and at least one second electrode, in which the at least one first electrode is electrically connected to the n+ region and the at least one second electrode is electrically connected to the p+ region; and

a first trench and a second trench disposed on each of the plurality of solar cells, wherein the first trench is disposed on the one side of the semiconductor substrate and the second trench is disposed on the other opposite facing side of the semiconductor substrate, the first and the second trenches are separated from each other.

Since the solar cell module includes each of the plurality of solar cells including the at least one first electrode and the at least one second electrode disposed on the one side of a semiconductor substrate and the first and second trenches disposed on each of the plurality of solar cells, the trenches can prevent electrons and holes from moving among the plurality of solar cells without separating each solar cell of the plurality of solar cells. Accordingly, the solar cell module can have an effect of separating each solar cell of the plurality of solar cells. In addition, since each of the plurality of solar cells can be disposed in a substantially small area with an improved process margin and can be more easily wired in series, the solar cell module can accomplish a substantially high voltage per unit area.

A plurality of the n+ and p+ regions included in the solar cell module may be alternately disposed on the one side of the semiconductor substrate.

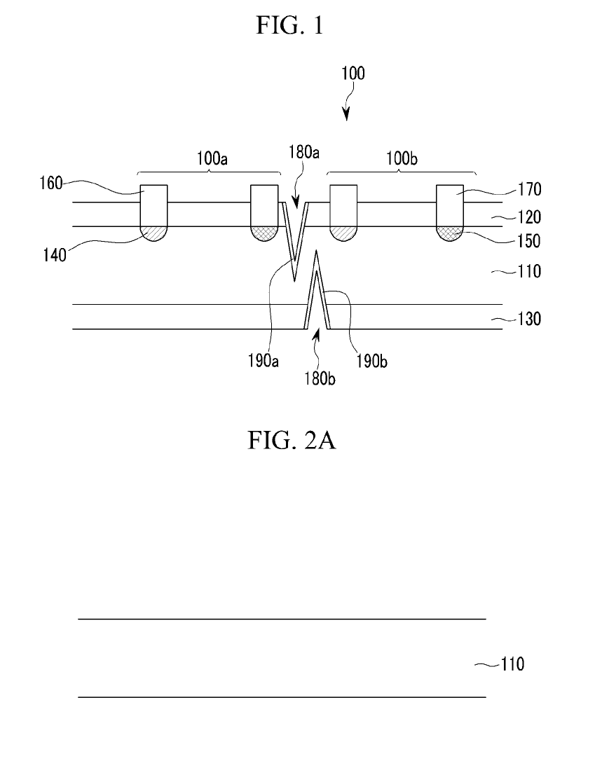

FIG. 1 is a partial cross-sectional view of a solar cell module 100 according to one aspect of the invention. The solar cell module 100 includes a plurality of solar cells 100a and 100b. Each of the solar cells 100a and 100b includes one n+ region 140, one p+ region 150, one first electrode 160, and one second electrode 170. In addition, the solar cell module 100 includes first and second trenches 180a and 180b disposed on the solar cells 100a and 100b.

Hereinafter, for better understanding and ease of description, a “front side” indicates a side receiving the solar energy in a semiconductor substrate 110, and a “rear side” indicates the other opposite facing side to the front side of the semiconductor substrate 110.

Still referring to FIG. 1, the solar cell 100a and the solar cell 100b included in the solar cell module 100 include a semiconductor substrate 110, the n+ region 140 and the p+ region 150 disposed on the one side of the semiconductor substrate 110 and separated from each other, a first electrode 160 electrically connected to the n+ region 140, and a second electrode 170 electrically connected to the p+ region 150.

The semiconductor substrate 110 may include crystalline silicon (e.g., a silicon wafer) or compound semiconductors. The semiconductor substrate 110 may be a semiconductor substrate doped with a p-type impurity or an n-type impurity. Herein, the p-type impurity may be a Group III element such as boron (B), and the n-type impurity may be a Group V element such as phosphorus (P), for example.

A surface of the semiconductor substrate 110 may be textured. The surface-textured semiconductor substrate 110 may, for example, have protrusions and depressions like a pyramid or pores like a honeycomb. The surface-textured semiconductor substrate 110 may have an enlarged surface area to substantially enhance a light-absorption rate and decrease reflectivity of light, resultantly improving efficiency of a solar cell.

The semiconductor substrate 110 may have a thickness from about 50 μm to about 300 μm. When the semiconductor substrate 110 has a thickness within the abovementioned range, the solar cell module 100 may be more easily manufactured, reducing processing time and costs. In particular, the semiconductor substrate 110 may have a thickness from about 50 μm to about 200 μm.

The semiconductor substrate 110 includes a plurality of n+ regions 140 and p+ regions 150 separated from each other and disposed on the one side.

The n+ region 140 is doped with an n-type impurity, so that the n+ region 140 can more easily collect produced electrons into an electrode. In addition, the p+ region 150 is doped with a p-type impurity so that the p+ region 150 can more easily collect produced holes into an electrode.

The first electrode 160 is disposed on the n+ region 140. The first electrode 160 plays a role of collecting electrons produced from the semiconductor substrate 110 and transporting the electrons, and can be made of a barrier metal such as silver (Ag), aluminum (Al), copper (Cu), tungsten (W), titanium (Ti), titanium tungsten (TiW), or cobalt (Co), for example, but is not limited thereto.

The second electrode 170 is disposed on the p+ region 150. The second electrode 170 plays a role of collecting holes, and can be made of a barrier metal such as silver (Ag), aluminum (Al), copper (Cu), tungsten (W), titanium (Ti), titanium tungsten (TiW), or cobalt (Co), for example, but is not limited thereto.

Still referring to FIG. 1, the semiconductor substrate 110 includes an anti-reflection coating layer 120 on a region other than regions disposed by the first electrode 160, the second electrode 170, and the first trench 180a, but is not limited thereto and may not include the anti-reflection coating layer 120. The anti-reflection coating layer 120 may include an insulating material that reflects substantially little light. The anti-reflection coating layer 120 may include an oxide such as aluminum oxide (Al₂O₃), silicon oxide (SiO₂), titanium oxide (TiO₂ or TiO₄), magnesium oxide (MgO), cerium oxide (CeO₂), or any combinations thereof, a nitride such as aluminum nitride (AlN), silicon nitride (SiNₓ), titanium nitride (TiN), or any combinations thereof, or an oxynitride such as aluminum oxynitride (AlON), silicon oxynitride (SiON), titanium oxynitride (TiON), or any combinations thereof, but is not limited there to. The anti-reflection coating layer 120 may be provided as a single layer or a multiple layer.

The anti-reflection coating layer 120 may have a thickness from about 5 nanometers (nm) to about 300 nm, and in particular, from about 50 nm to about 80 nm.

The anti-reflection coating layer 120 is disposed on the front side of the semiconductor substrate 110, and can decrease reflectance of light and increase selectivity of particular wavelength regions. In addition, the anti-reflection coating layer 120 can substantially improve contact characteristics with silicon on the front side of the semiconductor substrate 110, resultantly increasing efficiency of a solar cell.

The semiconductor substrate 110 may further include a dielectric layer 130 on the rear side. FIG. 1 shows solar cells 100a and 100b including the dielectric layer 130, but is not limited thereto and may not include a dielectric layer 130. The dielectric layer 130 prevents charges from being recombined and a current from leaking, resultantly improving efficiency of a solar cell. In addition, the dielectric layer 130 may play a role of passivating the rear side of the semiconductor substrate 110.

The dielectric layer 130 may include a material selected from the group consisting of an oxide, a nitride, an oxynitride, or any combinations thereof, for example. The oxide includes aluminum oxide (Al₂O₃), silicon oxide (SiO₂), titanium oxide (TiO₂ or TiO₄), or any combinations thereof, the nitride includes aluminum nitride (AlN), silicon nitride (SiNₓ), titanium nitride (TiN), or any combinations thereof, and the oxynitride includes aluminum oxynitride (AlON), silicon oxynitride (SiON), titanium oxynitride (TiON), or any combinations thereof, for example.

The dielectric layer 130 may be provided as a single layer or a multiple layer. Further, the dielectric layer 130 may have a thickness from about 10 nm to about 500 nm. When the dielectric layer 130 has a thickness within the abovementioned range, the dielectric layer 130 may more effectively passivate the rear side of the semiconductor substrate 110 and increase a photoelectric current by reflecting long-wavelength light again into the semiconductor substrate 110, and also may accomplish excellent chemical resistance. In particular, the dielectric layer 130 may have a thickness from about 100 nm to about 200 nm.

Still referring to FIG. 1, the solar cell module 100 according to one aspect of the invention includes the first trench 180a disposed on the solar cells 100a and 100b, where in the first trench 180a is disposed on the front side of the semiconductor substrate 110, and the second trench 180b disposed on the solar cells 100a 100b, wherein the second trench 180b is disposed on the rear side of the semiconductor substrate 110. The first and second trenches 180a and 180b are separated from each other and not connected to each other.

When the solar cells 100a and 100b include no anti-reflection coating layer 120 and no dielectric layer 130, the depth of the first trench 180a refers to a length measured from the front surface of the semiconductor substrate 110 to the end of the first trench 180a. The depth of the second trench 180b refers to a length measured from the rear surface of the semiconductor substrate 110 to the end of the second trench 180b.

Herein, a sum of depths of the first and second trenches 180a and 180b may be greater than the thickness of the semiconductor substrate 110. In addition, a length difference calculated by subtracting the thickness of the semiconductor substrate 110 from a sum of depths of the first and second trenches 180a and 180b may be greater than a length of a mean free path of electrons and holes produced from the semiconductor substrate. When the first and second trenches 180a and 180b have a depth within a particular range, the electrons and holes produced from the semiconductor substrate 110 can be more effectively prevented from moving between the solar cell 100a and the solar cell 100b. Accordingly, the solar cell module 100 may have the same effect as separation of the solar cell 100a and the solar cell 100b even though they are not actually separated.

In addition, when the solar cells 100a and 100b include the anti-reflection coating layer 120, a depth of the first trench 180a refers to a length measured from the front surface of the semiconductor substrate 110 to the end of the first trench 180a plus a thickness of the anti-reflection coating layer 120. When the solar cells 100a and 100b include the dielectric layer 130, a depth of the second trench 180b refers to a length from the rear surface of the semiconductor substrate 110 to the end of the second trench 180b plus a thickness of the dielectric layer 130.

When the solar cells 100a and 100b include the anti-reflection coating layer 120, the dielectric layer 130, or the anti-reflection coating layer 120 and the dielectric layer 130, a sum of depths of the first trench 180a and the second trench 180b may be greater than each sum calculated by adding a thickness of the anti-reflection coating layer 120, a thickness of the dielectric layer 130, or a sum of thicknesses of the anti-reflection coating layer 120 and the dielectric layer 130, respectively, to the thickness of the semiconductor substrate 110. In addition, a length difference calculated by subtracting each sum calculated by adding a thickness of the anti-reflection coating layer 120, a thickness of the dielectric layer 130, or a sum of thicknesses of the anti-reflection coating layer 120 and the dielectric layer 130, respectively, to a thickness of the semiconductor substrate 110 from a sum of depths of the first and second trenches 180a and 180b may be greater than a length of a mean free path of electrons and holes produced from the semiconductor substrate. When the first and second trenches 180a and 180b have a depth within the abovementioned range, electrons and holes produced from the semiconductor substrate 110 may be more effectively prevented from moving between the solar cell 100a and the solar cell 100b. Accordingly, the solar cell module 100 may have the same effect as separation of the solar cell 100a and the solar cell 100b even though they are not actually separated.

The first trench 180a may have a width from about 20 μm to about 50 μm, and the second trench 180b may have a width from about 20 μm to about 50 μm. When the first and second trenches 180a and 180b have a width within the abovementioned range, the first and second trenches 180a and 180b may be more easily disposed in a simpler, faster, and cheaper way.

The solar cell module 100 may further include a first passivation layer 190a on the surface of the first trench 180a and a second passivation layer 190b on the surface of the second trench 180b.

The first and second passivation layers 190a and 190b respectively play a role of protecting a part exposed by the first and second trenches 180a and 180b in the semiconductor substrate 110.

The first and second passivation layers 190a and 190b may include the material used to dispose the aforementioned anti-reflection coating layer 120 or the dielectric layer 130.

The first and second passivation layers 190a and 190b may be provided in a single layer or multiple layers and may have a thickness from about 10 nm to about 500 nm. When the first and second passivation layers 190a and 190b have a thickness within the abovementioned range, the first and second passivation layers 190a and 190b may more effectively passivate the semiconductor substrate 110.

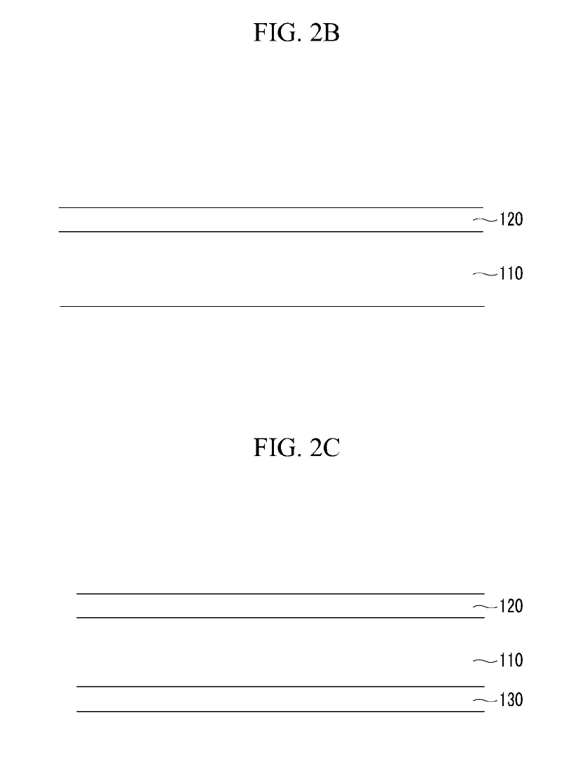

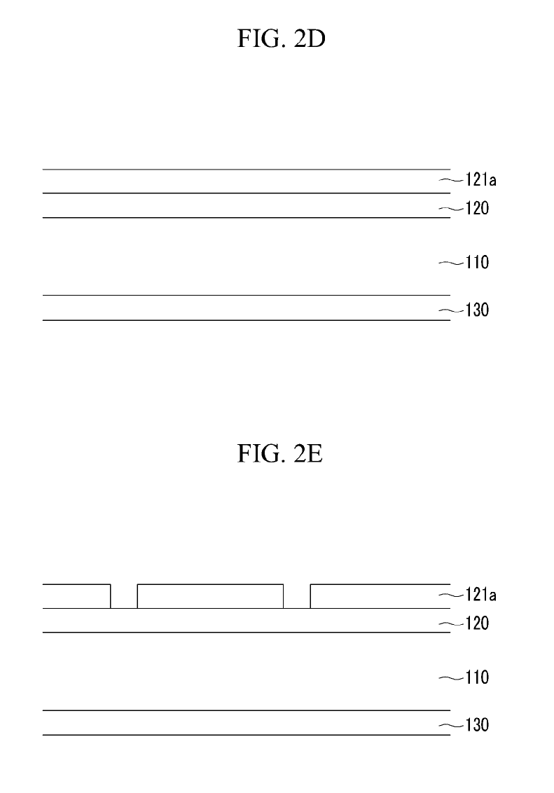

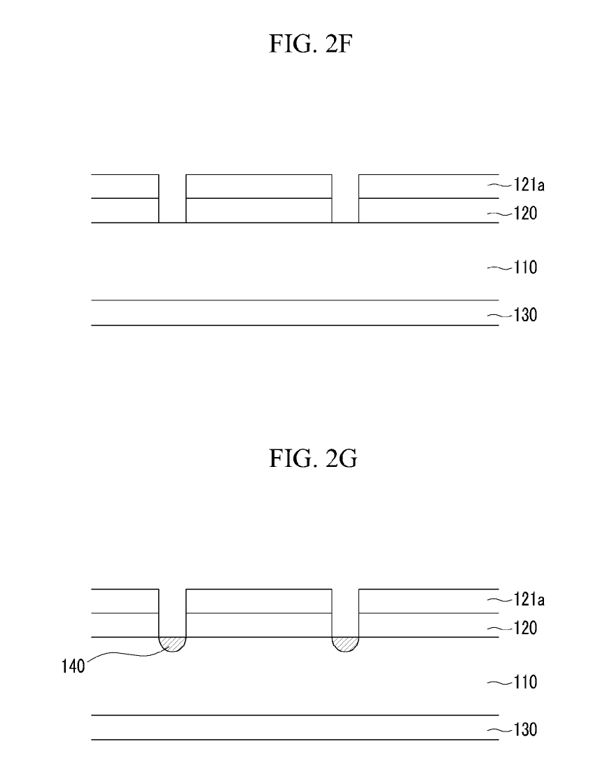

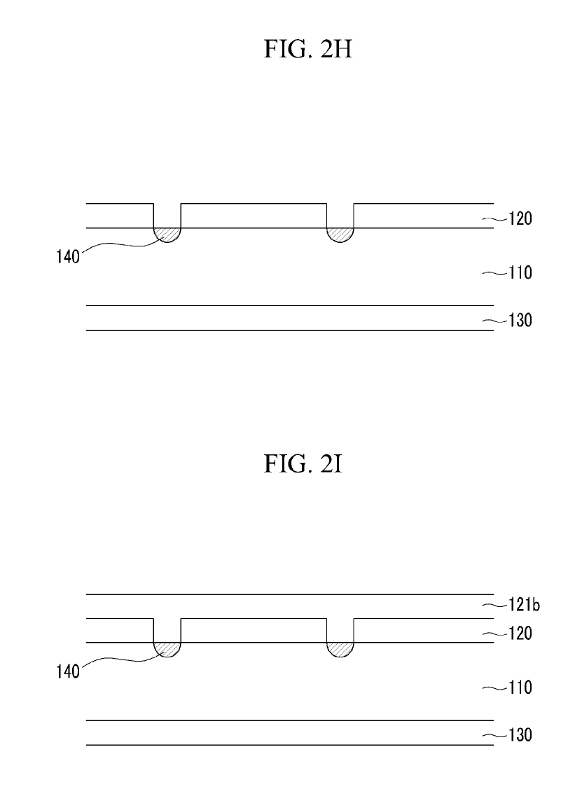

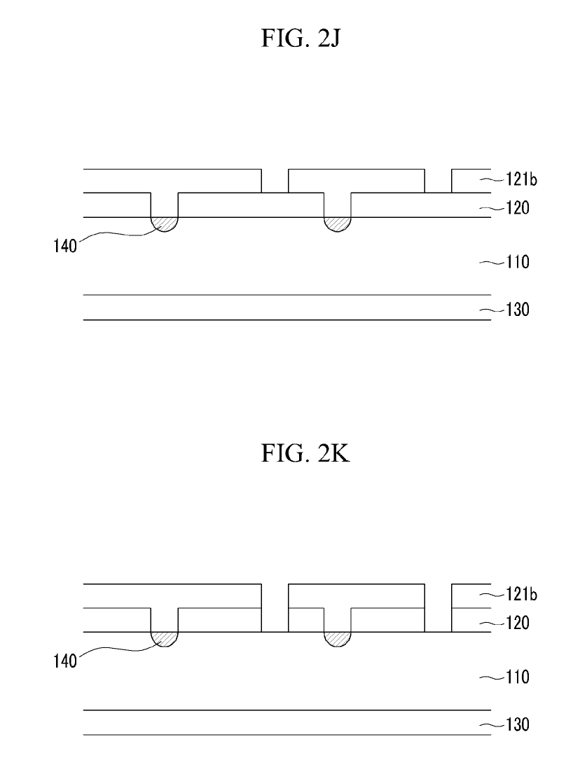

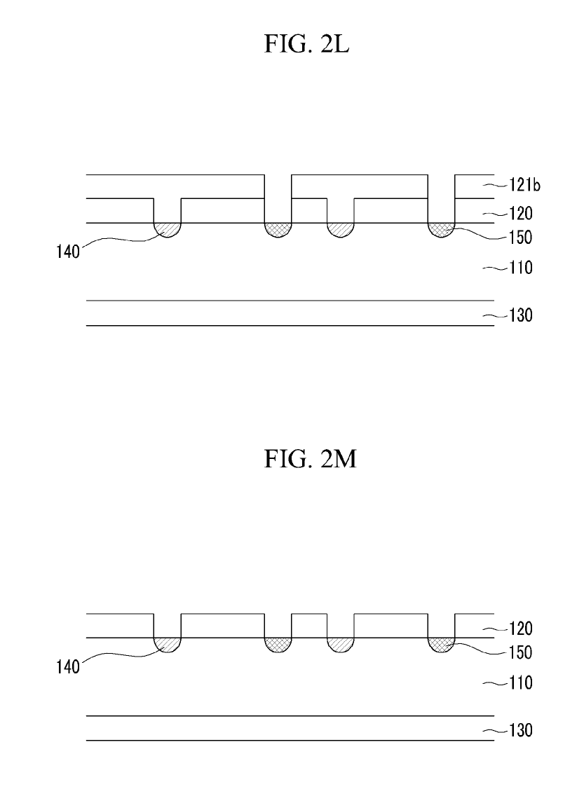

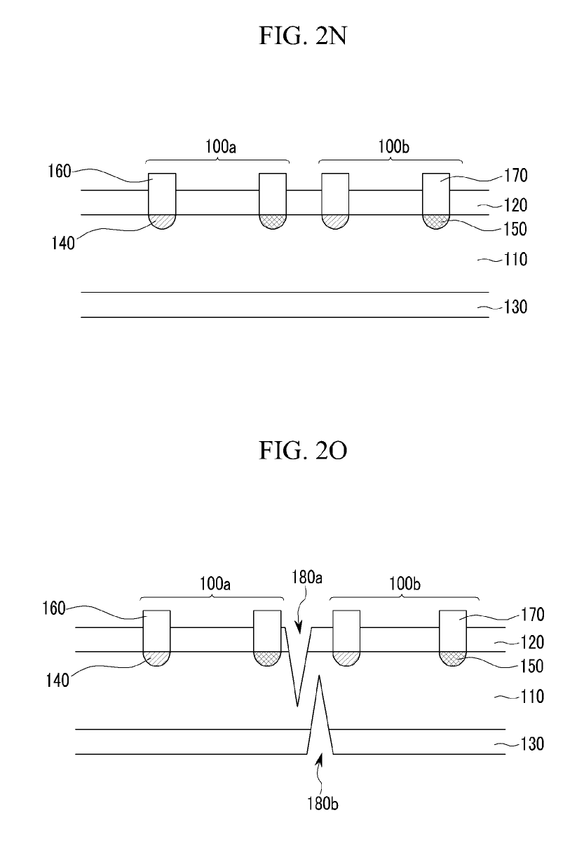

Hereinafter, a method of manufacturing a solar cell module according to another aspect of the present invention will be described with reference to FIGS. 2A to 2O along with FIG. 1.

FIGS. 2A to 2O are partial cross-sectional views showing processes of manufacturing a solar cell module 100 according to another aspect of the present invention embodiment.

Referring to FIG. 2A, a semiconductor substrate 110 include a material such as silicon or a silicon wafer, for example. The semiconductor substrate 110 may be doped with a p-type impurity or an n-type impurity.

A surface of the semiconductor substrate 110 may be textured. The surface texturing may be performed by a wet process using a strong acid solution such as nitric acid and hydrofluoric acid or a strong base solution such as potassium hydroxide and sodium hydroxide, or by a dry process using plasma, but is not limited thereto.

Referring to FIG. 2B, an anti-reflection coating layer 120 is disposed on the front surface of the semiconductor substrate 110. FIG. 2B shows a process of disposing the anti-reflection coating layer 120. However, the anti-reflection coating layer 120 is not limited thereto. The anti-reflection coating layer 120 may be disposed by disposing silicon nitride by a plasma enhanced chemical vapor deposition (“PECVD”) method, but is not limited thereto and may be disposed with different materials and different methods.

Referring to FIG. 2C, a dielectric layer 130 may be disposed on the rear side of the semiconductor substrate 110. FIG. 2C shows a process of disposing the dielectric layer 130, but is not limited thereto and may not include a process of disposing the dielectric layer 130. The dielectric layer 130 can be disposed by disposing a material (e.g., silicon nitride) by a plasma enhanced chemical vapor deposition (“PECVD”) method, for example, but is not limited thereto and may be disposed with different materials and different methods.

Referring to FIGS. 2D to 2H, a plurality of n+ regions 140 are disposed on the front surface of the semiconductor substrate 110.

In particular, a first photoresist 121a is disposed on the anti-reflection coating layer 120, photo-radiated using a patterned mask (not shown), and developed using a developing solution to remove parts of the first photoresist 121a overlapped with the plurality of n+ regions 140 to be disposed. Parts of the anti-reflection coating layer 120 overlapped with the plurality of n+ regions 140 to be disposed may be etched using chlorine (Cl₂) gas, or a fluorine-based gas such as sulfer hexaflourine (SF₆), tetrafluoromethane (CF₄), hexafluoroethane (C₂F₆), hexafluoropropylene (C₃F₆), octafluorocyclobutane (C₄F₈), nitrogen trifluoride (NF₃) through a dry etching process, for example. Then, the plurality of n+ regions 140 is disposed by doping a group V element such as phosphorus (P) on a region exposed by the etching process in the semiconductor substrate 110. The doping may be performed by a vapor diffusion method, a solid-phase diffusion method, an ion implantation method, for example, but is not limited thereto. The first photoresist 121a is removed.

Referring to FIGS. 2I to 2M, a plurality of p+ regions 150 are disposed on the front surface of the semiconductor substrate 110 separated from the plurality of n+ regions 140.

In particular, a second photoresist 121b is disposed on the anti-reflection coating layer 120, photo-radiated by a patterned mask (not shown), and developed with a developing solution to remove parts of the second photoresist 121b overlapped with the plurality of p+ regions 150 to be disposed. The parts of the anti-reflection coating layer 120 overlapped with the plurality of the p+ regions 150 to be disposed may be etched using Cl₂ gas, or a fluorine-based gas such as sulfer hexaflourine (SF₆), tetrafluoromethane (CF₄), hexafluoroethane (C₂F₆), hexafluoropropylene (C₃F₆), octafluorocyclobutane (C₄F₈), nitrogen trifluoride (NF₃) through a dry etching process, for example. The semiconductor substrate 110 exposed by the etching may be doped with a Group III element such as boron (B), for example, resultantly disposing the plurality of p+ regions 150. The doping may be performed by a vapor diffusion method, a solid-phase diffusion method, an ion implantation method, but is not limited thereto. The second photoresist 121b is removed.

The plurality of n+ regions 140 and the p+ regions 150 may be alternately disposed on the one side of the semiconductor substrate.

Referring to FIG. 2N, a first electrode 160 is electrically connected to the n+ region 140 of the semiconductor substrate 110, and a second electrode 170 is electrically connected to the p+ region 150 of the semiconductor substrate 110.

The first and second electrodes 160 and 170 may be disposed by coating an electrode-forming material (e.g., a metal) by a chemical vapor deposition (“CVD”) method and etching the electrode-forming material by using a photoresist, for example.

Still referring to FIG. 2N, the first and second electrodes 160 and 170 may be disposed by a chemical vapor deposition (“CVD”) method and by an etching process using a photoresist, but are not limited thereto and can include various other methods for disposing an electrode.

Accordingly, the solar cell module 100 is fabricated to include a plurality of solar cells 100a and 100b.

Referring to FIG. 2O, between the solar cell 100a and 100b, a first trench 180a is disposed on the front side of the semiconductor substrate 110 and a second trench 180b is disposed on the rear side of the semiconductor substrate 110.

The first and second trenches 180a and 180b can be disposed by respectively etching the front side and the rear side of the semiconductor substrate 110 between the solar cell 100a and the solar cell 100b with a laser. The laser may include an yttrium aluminium garnet (“YAG”) laser or a carbon dioxide (CO₂) laser, but is not limited thereto. In addition, the laser can be controlled regarding strength, radiation time, for example, to regulate depths and widths of the first and second trenches 180a and 180b.

The front and rear sides of the semiconductor substrate 110 are etched with a laser, and then a region damaged by the laser may be further removed. The damaged region may be removed by a wet etching process including potassium hydroxide (KOH), sodium hydroxide (NaOH), Radio Corporation of America (“RCA”) cleaning, or a dry etching process using Chlorine (Cl₂) gas or a fluorine-based gas such as sulfer hexaflourine (SF₆), tetrafluoromethane (CF₄), hexafluoroethane (C₂F₆), hexafluoropropylene (C₃F₆), octafluorocyclobutane (C₄F₈), nitrogen trifluoride (NF₃), for example, but is not limited thereto.

The laser etching process for disposing the first trench 180a and the second trench 180b may include a sawing process, a trench etching process, or a combination thereof, but is not limited thereto.

Though not shown in FIG. 2O, a first passivation layer may be further included on a surface of the first trench 180a and a second passivation layer may be further included on a surface of the second trench 180b. The first and second passivation layers may be disposed by disposing silicon nitride by a plasma enhanced chemical vapor deposition (“PECVD”) method, but are not limited thereto, and may be disposed by other materials and methods.

According to one aspect of the present invention, a solar cell module includes a plurality of solar cells including a first electrode and a second electrode disposed on the front side of a semiconductor substrate, and a first trench and a second trench disposed on each of the plurality of solar cells, wherein the first trench is disposed on the front side of the semiconductor substrate and the second trench is disposed on the other opposite facing side of the semiconductor substrate, so that electrons and holes produced from the semiconductor substrate can be effectively prevented from moving between each of the plurality of solar cells. In addition, the solar cell module has an improved process margin and can include more solar cells per unit area, thereby more easily wiring solar cells and accomplishing high voltage per unit area. Accordingly, the solar cell module can be applied to various appliances, such as a mobile phone, a camera, a camcorder, a clock or a watch, an automobile, a generator, for example.

In addition, another aspect of the present invention provides a method of manufacturing a solar cell module including a plurality of solar cells, in which each of the plurality of solar cells is not separated but includes the first and second trenches. Therefore, since a solar cell module according to one aspect of the present invention has a substantially improved process margin and needs no additional and complex process, such as arrangement and distance control, but not limited thereto, resultantly the solar cell module can be fabricated in a simpler, faster, and cheaper way.

The present invention should not be construed as being limited to the aspects of the present invention set forth herein. Rather, these aspects of the present invention are provided so that this disclosure will be thorough and complete and will fully convey the concept of the present invention to those skilled in the art.

While the present invention has been particularly shown and described with reference to aspects of the present invention thereof, it will be understood by those of ordinary skill in the art that various changes in form and details may be made therein without departing from the spirit or scope of the present invention as defined by the following claims.

What is claimed is:

1. A solar cell module comprising:
a plurality of solar cells connected to one another;
each solar cell of the plurality of solar cells independently including a semiconductor substrate;
one n+ region and one p+ region disposed on one side of the semiconductor substrate and separated from each other;
at least one first electrode and at least one second electrode, in which the at least one first electrode is electrically connected to the n+ region and the at least one second electrode is electrically connected to the p+ region; and
a first trench and a second trench disposed on each of the plurality of solar cells, wherein the first trench is disposed on the one side of the semiconductor substrate and the second trench is disposed on the other opposite facing side of the semiconductor substrate, the first and second trenches being separated from each other.

2. The solar cell module of claim 1, wherein each solar cell of the plurality of solar cells independently comprises:
the n+ region;
the at least one first electrode electrically connected to the n+ region;
the p+ region; and
the at least one second electrode electrically connected to the p+ region.

3. The solar cell module of claim 1, wherein a plurality of the n+ and p+ regions included in the solar cell module are alternately disposed on the one side of the semiconductor substrate.

4. The solar cell module of claim 1, wherein the semiconductor substrate has a thickness from about 50 micrometers to about 300 micrometers.

5. The solar cell module of claim 1, wherein a sum of depths of the first and second trenches is greater than a thickness of the semiconductor substrate.

6. The solar cell module of claim 1, wherein a difference calculated by subtracting a thickness of the semiconductor substrate from a sum of depths of the first and second trenches is greater than a length of a mean free path of electrons and holes produced from the semiconductor substrate.

7. The solar cell module of claim 1, wherein the first trench has a width from about 20 micrometers to about 50 micrometers.

8. The solar cell module of claim 1, wherein the second trench has a width from about 20 micrometers to about 50 micrometers.

9. The solar cell module of claim 1, further comprising an anti-reflection coating layer on one side of the semiconductor substrate.

10. The solar cell module of claim 1, further comprising a dielectric layer on the other opposite facing side of the semiconductor substrate.

11. The solar cell module of claim 1, further comprising a first passivation layer on a surface of the first trench.

12. The solar cell module of claim 1, further comprising a second passivation layer on a surface of the second trench.

13. A method of manufacturing a solar cell module, the method comprising:
preparing a plurality of solar cells connected to one another; and
disposing a first trench and a second trench on each of the plurality of solar cells,
wherein the solar cells independently comprises a semiconductor substrate, one n+ region and one p+ region disposed on one side of the semiconductor substrate and separated from each other, and at least one first electrode and at least one second electrode in which the at least one first electrode is electrically connected to the n+ region and the at least one second electrode is electrically connected to the p+ region and the first trench is disposed on the one side of the semiconductor substrate and the second trench is disposed on the other opposite facing side of the semiconductor substrate, the first and second trenches are separated each other.

14. The method of claim 13, wherein each solar cell of the plurality of solar cells independently comprises:
the n+ region;
the at least one first electrode electrically connected to the n+ region;
the p+ region; and
the at least one second electrode electrically connected to the p+ region.

15. The method of claim 13, wherein the solar cell module comprises a plurality of the n+ and p+ regions disposed alternately on the one side of the semiconductor substrate.

16. The method of claim 13, wherein each solar cell of the plurality of solar cells further comprises an anti-reflection coating on the one side of the semiconductor substrate.

17. The method of claim 13, wherein each solar cell of the plurality of solar cells further comprises a dielectric layer on the other opposite facing side of the semiconductor substrate.

18. The method of claim 13, wherein the first and second trenches are disposed by a laser etching process, a sawing process, a trench etching process, or any combinations thereof.

19. The method of claim 18, wherein the first and second trenches are disposed by removing a part that is damaged by a laser etching process, a sawing process, a trench etching process, or any combinations thereof.

20. The method of claim 13, which further comprises disposing a first passivation layer on a surface of the first trench, disposing a second passivation layer on a surface of the second trench.
